(19) United States
(12) Patent Application Publication
(10) Pub. No.: US 2022/0162395 A1
(43) Pub. Date: May 26, 2022

(54) SILICONE RUBBER-BASED CURABLE COMPOSITION,STRUCTURE, WEARABLE DEVICE, AND METHOD FOR MANUFACTURING STRUCTURE

(71) Applicant: SUMITOMO BAKELITE CO., LTD., Shinagawa-ku, Tokyo (JP)

(72) Inventors: Jun Okada, Tokyo (JP); Yumiko Yamanoi, Tokyo (JP); Motoki Sato, Tokyo (JP)

(21) Appl. No.: 17/434,764

(22) PCT Filed: Jan. 30, 2020
(86) PCT No.: PCT/JP2020/003513

§ 371 Date: Aug. 30, 2021

(30) Foreign Application Priority Data
Mar. 8, 2019 (JP) 2019-043023

(51) Int. Cl. C08G 77/20; C08K 3/36; H05K 1/03

(52) U.S. Cl. CPC C08G 77/20; C08K 3/36; H05K 2201/0209; C08K 2201/006; H05K 2201/0162; H05K 1/0373

(57) ABSTRACT

A silicone rubber-based curable composition of the present invention include a vinyl group-containing organopolysiloxane (A) and silica particles (C), in which a ratio of change in a cut length, in a test piece formed of a cured product of the silicone rubber-based curable composition with the number of times of bending of 50,000, in a case where the test piece is used to perform a De Mattia-type bending resistance test in accordance with JIS K 6260 and the cut length is measured on the basis of a predetermined procedure, is equal to or more than 1.1 and equal to or less than 11.5.

### TECHNICAL FIELD

The present invention relates to a silicone rubber-based curable composition, a structure, a wearable device, and a method for manufacturing a structure.

### BACKGROUND ART

Various developments in the durability of a silicone rubber have hitherto been made. As a technique in such a field, for example, the technique described in Patent Document 1 is known. Patent Document 1 describes that elongation fatigue resistance can be evaluated based on the number of elongations up to breaking by repeating 100% elongation operations, and also describes a silicone rubber (cured product of a curable silicone rubber composition) having the number of elongations of 2,100,000 (Example 1 of Patent Document 1).

### RELATED DOCUMENT

### Patent Document

[Patent Document 1] Japanese Laid-open patent publication No. 2008-222849

### SUMMARY OF THE INVENTION

### Technical Problem

However, as a result of investigations conducted by the present inventors, it was found that there is room for improvement in terms of durability against repeated bending deformation in a cured product of the curable silicone rubber composition described in Patent Document 1.

### Solution to Problem

In the technical field of a silicone rubber, investigations on the characteristics during elongation have been generally carried out.

However, the characteristics during repeated bending have not been sufficiently investigated.

The present inventors have conducted investigations, and have thus found that the bending resistance of a molded product of a silicone rubber-based curable composition in repeated bending can be evaluated by using a De Mattia-type bending resistance test. As a result of further investigations, it was found that test conditions for a De Mattia-type bending resistance test are appropriately set in accordance with JIS K 6260 and then a ratio of change in a cut length in a test piece with a cut is used as an index, whereby the bending resistance can thus be controlled. The present inventors have conducted further intensive studies based on these findings, and have thus found that the durability against repeated bending deformation is improved in a molded product of a silicone rubber-based curable composition by adjusting a ratio of change in a cut length in a test piece with the number of times of bending of 50,000 within a predetermined range, thereby leading to completion of the present invention.

According to the present invention,

there is provided a silicone rubber-based curable composition including a vinyl group-containing organopolysiloxane (A), and

silica particles (C),

in which in a case where a De Mattia-type bending resistance test in accordance with JIS K 6260 is performed using a test piece formed of a cured product of the silicone rubber-based curable composition, a ratio (L₅/L₀) of change in a cut length in the test piece with the number of times of bending of 50,000 is equal to or more than 1.1 and equal to or less than 11.5, the ratio being measured on the basis of the following procedure.

(Procedure)

The silicone rubber-based curable composition is pressed at 170° C. and 10 MPa for 15 minutes, and subsequently heated at 200° C. for 4 hours to manufacture a strip-shaped test piece having a width of 25 mm, a length of 150 mm, and a thickness of 6.3 mm in accordance with JIS K 6260.

In the center of the obtained test piece, a cut having a length of 2.03 mm, penetrating the test piece, is formed in parallel to a width direction. The initial cut length is defined as L₀.

Subsequently, the test piece with the cut is attached between grippers of a tester, the De Mattia-type bending resistance test is performed based on the following test conditions, and a cut length (mm) in the test piece after a predetermined number of times of bending is measured.

An average value in a case where the De Mattia-type bending resistance test is performed three times is used as the cut length. The average value of the cut length is defined as L₅.

The ratio of change in the cut length is calculated based on an expression: L₅/L₀.

(Test Conditions)
Test standard: In accordance with JIS K 6260
Tester: De Mattia bending-cracking tester
Test temperature: 23±2° C.
Maximum distance between grippers: 75 mm
Reciprocating distance: 57 mm
Test speed: 300±10 times/minute
Number of tests: n=3

Moreover, according to the present invention, there is provided a structure including a cured product of the silicone rubber-based curable composition.

In addition, according to the present invention,

there is provided a wearable device having a wiring substrate including a wiring and a substrate,

in which apart of the wiring and/or the substrate in the wiring substrate is formed of a cured product of the silicone rubber-based curable composition.

In addition, according to the present invention,

there is provided a method for manufacturing a structure, including a step of curing the silicone rubber-based curable composition, and

a step of obtaining a structure including a cured product of the silicone rubber-based curable composition.

### Advantageous Effects of Invention

According to the present invention, there is provided a silicone rubber-based curable composition which can realize a molded product having excellent durability against repeated bending deformation, a structure, a wearable device, and a method for manufacturing a structure.

### BRIEF DESCRIPTION OF THE DRAWINGS

The above-described objectives and other objectives, features, and advantages will be further clarified by suitable embodiments described below and the accompanying drawings below.

FIGS. 1A and 1B are schematic views showing an example of the configuration of a mold.

FIGS. 2A and 2B are schematic views showing an example of the configuration of a test piece.

FIG. 3 is a schematic view showing an example of the configuration of a De Mattia-type tester.

### DESCRIPTION OF EMBODIMENTS

Hereinafter, embodiments of the present invention will be described with reference to drawings. Further, in all drawings, similar components are designated by the same reference numerals, and description thereof will not be repeated as appropriate. In addition, the drawings are schematic views and do not match actual dimensional ratios.

An overview of the silicone rubber-based curable composition of the present embodiment will be described.

The silicone rubber-based curable composition of the present embodiment include a vinyl group-containing organopolysiloxane (A) and silica particles (C), in which in a case where a De Mattia-type bending resistance test in accordance with JIS K 6260 is performed using a test piece formed of a cured product of the silicone rubber-based curable composition, a ratio (1,5/L₀) of change in a cut length in the test piece with the number of times of bending of 50,000 satisfies a range of equal to or more than 1.1 and equal to or less than 11.5, the ratio being measured on the basis of the following procedure.

(Procedure)

The silicone rubber-based curable composition is pressed at 170° C. and 10 MPa for 15 minutes, and subsequently heated at 200° C. for 4 hours to manufacture a grooved test piece having a predetermined shape in accordance with JIS K 6260.

A cut having a predetermined length (2.03 mm) penetrating the test piece is formed in parallel to a width direction in the center of a groove of the obtained test piece. The initial cut length is defined as L₀.

Subsequently, the test piece with the cut is attached between grippers of a tester, the De Mattia-type bending resistance test is performed based on the following test conditions, and a cut length (mm) in the test piece after a predetermined number of times of bending is measured.

An average value in a case where the De Mattia-type bending resistance test is performed three times is used as the cut length. The average value of the cut length is defined as L₅.

The ratio of change in the cut length is calculated based on an expression: L₅/L₀.

(Test Conditions)
Test standard: In accordance with JIS K 6260
Tester: De Mattia bending-cracking tester
Test temperature: 23±2° C.
Maximum distance between grippers: 75 mm
Reciprocating distance: 57 mm
Test speed: 300±10 times/minute
Number of tests: n=3

(Test Pieces)
Test piece: A strip-shaped test piece having dimensions of a width of 25±1 mm, a length of 140 to 155 mm, and a thickness of 6.30±0.3 mm, which has a groove part in the center in the longitudinal direction (not penetrating in the thickness direction)
Cut of test piece: The length of the cut in the width direction of the test piece is 2.03 mm, the cut is located in the center in the width direction of the groove part, and penetrates the groove part in the thickness direction.

According to the findings of the present inventors, it was found that with regard to a molded product of a silicone rubber-based curable composition, the bending resistance during repeated bending can be evaluated by using a De Mattia-type bending resistance test.

However, in a case where an appropriate index is not set, the evaluation takes time and there is also a risk that a variation in the evaluation occurs. For example, in a case where the number of deformations up to breaking was used as an index in the same manner as the 100% elongation fatigue life of Patent Document 1, a period up to breaking was longer and a variation in the number of deformations occurred in some cases. In addition, it was found that in a case where a non-cut product was used as a test piece and the breaking state was used as an index, a considerable number of times of bending was required until a difference in the breaking state appeared, and even such the difference increased the variation in the breaking state.

Then, as a result of further investigations conducted by the present inventors, it was found that by appropriately setting test conditions for a De Mattia-type bending resistance test in accordance with JIS K 6260, and then using a ratio of change in the cut length in a test piece with a cut as a guideline, the bending resistance during repeated bending can be evaluated relatively quickly and stably with regard to a molded product of a silicone rubber-based curable composition, and the bending resistance can be controlled.

The present inventors have conducted further intensive studies, based on these findings, and have thus found that the bending resistance during repeated bending can be stably evaluated by using, as an index, a ratio of change in a cut length in a test piece with the number of times of bending of 50,000, and the durability against repeated bending deformation in a molded product of a silicone rubber-based curable composition can be improved by setting the index within the predetermined range.

A detailed mechanism is not clear, but is considered to be as follows: a silicone rubber structure having a small load during bending can be obtained by further improving the characteristics of a low hardness, a high tear strength, and a high elongation at break in a well-balanced manner by appropriately adjusting an inter-crosslink distance and a crosslinking density using the ratio of change in the cut as an index.

In the De Mattia-type bending resistance test, Lois an initial cut length before the De Mattia-type bending resistance test, and L₁, L₃, and L₅ are average values of the cut lengths with the number of times of bending of 10,000, 30,000, and 50,000, respectively, after the De Mattia-type bending resistance test.

The upper limit of the ratio (L₅/L₀) of change in the cut length in the test piece with the number of times of bending of 50,000 is equal to or less than 11.5, preferably equal to or less than 10.7, more preferably equal to or less than 8.0, and still more preferably equal to or less than 6.0. Thus, it is possible to realize a molded product having excellent durability against repeated bending deformation and having mechanical strength as a member. In addition, the upper limit of L₅/L₀ may be equal to or less than 5.3, or may be equal to or less than 4.0. Thus, bending-cracking resistance can be obtained.

On the other hand, the lower limit of the ratio (L₅/L₀) of change in the cut length may be equal to or more than 1.0, and may be equal to or more than 1.1.

As a result of the De Mattia-type bending resistance test using the silicone rubber-based curable composition, the upper limit of L₁/L₀ is, for example, equal to or less than 10.0, preferably equal to or less than 8.0, more preferably equal to or less than 6.0, and still more preferably equal to or less than 4.0. Thus, it is possible to realize a molded product having excellent durability against repeated bending deformation. Further, since the characteristics can be evaluated by a simpler evaluation method, the productivity of the silicone rubber-based curable composition can be improved. The lower limit of L₁/L₀ may be equal to or more than 1.0.

In addition, in a case where the initial cut length L₀ is 2.03 mm, the upper limit of the cut length L₅ in the test piece with the number of times of bending of 50,000 may be, for example, equal to or less than 22.5 mm, preferably equal to or less than 18.0 mm, and more preferably equal to or less than 15.0 mm. In addition, the upper limit of L₅ may be equal to or less than 10.8 mm. Thus, bending-cracking resistance can be obtained.

On the other hand, the lower limit of L₅ may be, for example, equal to or more than 2.1 mm, equal to or more than 2.2 mm, or equal to or more than 2.5 mm.

At this time, the upper limit of (L₅−L₀) may be, for example, equal to or less than 20.0 mm, equal to or less than 10.0 mm, equal to or less than 9.5 mm, or equal to or less than 8.4 mm. The lower limit of (L₅−L₀) may be equal to or more than 0.1 mm.

In addition, in a case where the initial cut length L₀ is 2.03 mm, the upper limit of the cut length L₃ with the number of times of bending of 50,000 may be, for example, equal to or less than 20.0 mm, preferably equal to or less than 15.0 mm, and more preferably equal to or less than 11.0 mm. In addition, the upper limit of L₅ may be equal to or less than 9.0 mm and equal to or less than 8.0 mm. Thus, bending-cracking resistance can be obtained.

On the other hand, the lower limit of L₃ may be, for example, equal to or more than 2.1 mm, or may be equal to or more than 2.2 mm.

In the present specification, a term “to” is used to indicate that an upper limit value and a lower limit value are included in a range unless otherwise specified.

The content of the silica particles (C) in the silicone rubber-based curable composition may be, for example, equal to or more than 10 parts by weight and equal to or less than 60 parts by weight with respect to 100 parts by weight of the vinyl group-containing organopolysiloxane (A). The upper limit of the content of the silica particles (C) is preferably equal to or less than 50 parts by weight, more preferably equal to or less than 35 parts by weight, and still more preferably equal to or less than 30 parts by weight. Thus, the durability against repeated bending deformation can be improved by making the silica content relatively low. By setting the content of the silica particles (C) to equal to or less than 35 parts by weight, the repeated bending durability can be stably increased.

In the present embodiment, it is possible to control the ratio of change in the cut length and the cut length, each described above, and an elongation at break, a tensile strength, a tear strength, and a hardness, each described later, for example, by appropriately selecting the type and blending amount of each component included in the silicone rubber-based curable composition, a method for preparing the silicone rubber-based curable composition, a method for manufacturing a silicone rubber, and the like. Among these, examples of factors for setting the ratio of change in a cut length, the cut length, and an elongation at break, a tensile strength, a tear strength, and a hardness, each of which will be described later, to desired numerical ranges are as follows: a vinyl group-containing linear organopolysiloxane (A1-1) having a relatively small amount of vinyl groups and having the vinyl groups only at terminals is used as the vinyl group-containing organopolysiloxane (A) to control the crosslinking density and the crosslinked structure of a resin; and the progress of a reaction between a silane coupling agent (D) and the silica particles (C) is more reliably made through a timing and a ratio of the vinyl group-containing organopolysiloxane (A) to be added, a blending ratio of the silica particles (C), a specific surface area of the silica particles (C), surface modification of the silica particles (C) with the silane coupling agent (D), addition of water, or the like.

Next, the characteristics of the silicone rubber-based curable composition of the present embodiment will be described.

(Measurement Conditions for Tear Strength)

A crescent-shaped test piece is manufactured using a cured product of the silicone rubber-based curable composition, and for the obtained crescent-shaped test piece, a tear strength is measured at 25° C. in accordance with JIS K 6252 (2001).

The lower limit of the tear strength of the cured product of the silicone rubber-based curable composition is, for example, equal to or more than 25 N/mm, preferably equal to or more than 28 N/mm, more preferably equal to or more than 30 N/mm, still more preferably equal to or more than 33 N/mm, and even still more preferably equal to or more than 35 N/mm. Thus, the durability of the silicone rubber during repeated use can be improved. In addition, the scratch resistance and the mechanical strength of the silicone rubber can be improved.

On the other hand, the upper limit of the tear strength is not particularly limited, but may be, for example, equal to or less than 70 N/mm, or equal to or less than 60 N/mm. Thus, various characteristics of the silicone rubber can be balanced.

(Measurement Conditions for Elongation at Break)

A dumbbell-shaped type-3 test piece is manufactured using a cured product of the silicone rubber-based curable composition, and for the obtained dumbbell-shaped type-3 test piece, an elongation at break is measured at 25° C. in accordance with JIS K 6251 (2004).

The lower limit of the elongation at break of the cured product of the silicone rubber-based curable composition is, for example, equal to or more than 500%, preferably equal to or more than 600%, and more preferably equal to or more than 700%, and may further be equal to or more than 780%, equal to or more than 800%, or equal to or more than 900%. Thus, the high stretchability and the durability of the silicone rubber can be improved.

On the other hand, the upper limit of the elongation at break is not particularly limited, but may be, for example, equal to or less than 2,000%, equal to or less than 1,800%, or equal to or less than 1,500%. Thus, various characteristics of the silicone rubber can be balanced.

(Measurement Conditions for Durometer Hardness A)

A sheet-shaped test piece is manufactured using a cured product of the silicone rubber-based curable composition, and for the obtained sheet-shaped test piece, a durometer hardness A is measured at 25° C. in accordance with JIS K 6253 (1997).

The upper limit of the durometer hardness A of a cured product of the silicone rubber-based curable composition is not particularly limited, but may be, for example, equal to or less than 70, preferably equal to or less than 55, and more preferably equal to or less than 50. Thus, it is possible to promote a balance of the curing physical properties of the silicone rubber. In addition, from the viewpoint of ease of deformation, the upper limit of the durometer hardness A may be equal to or less than 40, equal to or less than 35, or equal to or less than 30. Thus, it is possible to enhance the ease of deformation, which facilitates deformation such as bending and stretching in the silicone rubber.

On the other hand, the lower limit of the durometer hardness A is not particularly limited, but may be, for example, equal to or more than 10, preferably equal to or more than 20, and more preferably equal to or more than 25. Thus, the mechanical strength of the silicone rubber can be increased.

(Measurement Conditions for Tensile Strength)

A dumbbell-shaped type-3 test piece is manufactured using a cured product of the silicone rubber-based curable composition, and for the obtained dumbbell-shaped type-3 test piece, a tensile strength is measured at 25° C. in accordance with JIS K 6251 (2004).

The lower limit of the tensile strength of the cured product of the silicone rubber-based curable composition is, for example, equal to or more than 5.0 MPa, and may be preferably equal to or more than 6.0 MPa, equal to or more than 7.0 MPa, equal to or more than 8.0 MPa, or equal to or more than 12.0 MPa. Thus, the mechanical strength of the silicone rubber can be improved. In addition, a structure having excellent durability, which can endure repeated deformation, can be realized. On the other hand, the upper limit of the tensile strength is not particularly limited, but may be, for example, equal to or less than 25 MPa, or equal to or less than 20 MPa. Thus, various characteristics of the silicone rubber can be balanced.

The cured product (silicone rubber) of the silicone rubber-based curable composition of the present embodiment is formed into a molded product which has been processed and molded into various forms, depending on applications. The molded product may be molded into various shapes such as a sheet shape, a tubular shape, and a bag shape.

Since the silicone rubber-based curable composition has excellent durability against repeated bending modification, it can be suitably used for forming a molded product for a bendable member. The bendable member refers to a member that is repeatedly stressed in a bending direction in a use environment, for example. This bendable member may be used in a use environment where a stress is applied in a stretching direction.

Examples of the bendable member include a wearable device. That is, the silicone rubber-based curable composition can be suitably used for forming a part of a wearable device, that is, a part of an elastomer member or a bendable member included in the wearable device.

The wearable device is a wearable device that can be worn on a body or clothes, and preferably on a curved surface of the body or the clothes, and examples thereof include a medical sensor that detects phenomena from a living body, such as a heart rate, an electrocardiogram, a blood pressure, and a body temperature, a healthcare device, a foldable display, a stretchable LED array, a stretchable solar cell, a stretchable antenna, a stretchable battery, an actuator, and a wearable computer. It is possible to use the molded product as a member for forming an electrode, a wiring, a substrate, a movable member that is stretchable and bendable, an exterior member, and the like, which are used for such wearable devices.

Here, it was found that it is possible to apply a molded product of a silicone rubber-based curable composition to a bendable member in a wearable device having a wiring or wiring substrate, despite its simplicity in the process, by performing a wire bendability test using a fine wire made of a metal.

That is, a molded product of a silicone rubber-based curable composition, in which the occurrence of cracks and break is suppressed in a case where the molded product is, for example, bent at 90° with the number of times of bending of about 100 in the state where a wire is inserted in the molded product formed into a tubular molded product, can be suitably used for a bendable member that can be repeatedly bent, such as a wiring or a substrate in a wiring substrate of a wearable device.

Therefore, the silicone rubber-based curable composition of the present embodiment can be used to form a bendable member (a wiring and/or a substrate in a wiring substrate) which constitutes a part of a wearable device having a wiring or a wiring substrate, and is repeatedly bendable.

That is, an example of the wearable device has a wiring substrate including a wiring and a substrate, and a part of the wiring and/or the substrate in the wiring substrate may be formed of a cured product of the silicone rubber-based curable composition.

In addition, a structure including the cured product (molded product) of the silicone rubber-based curable composition can be used in various applications. Among the following applications, medical applications, robot applications, and electronic equipment applications are preferable, and robot applications and electronic equipment applications may be mentioned.

The structure including the cured product (silicone rubber) of the silicone rubber-based curable composition of the present embodiment can be used in, for example, medical applications such as medical instruments and equipment applications; automobile applications; robot applications such as industrial robots; electronic equipment applications: production equipment or daily use applications for an anti-vibration material, a seismic isolation material, a food hose, and the like; and roller members.

The silicone rubber of the present embodiment can constitute, for example, a part of a medical tube material; a sealing material; a packing material; a connector material; a key pad material; a drive mechanism; and a sensor, which are examples of the medical instruments and the equipment applications. For example, by applying a movable member made of a resin of the present embodiment to the medical tube, the medical tube is excellent in kink resistance, scratch resistance, insertability, and transparency, and is also excellent in resilience. In addition, examples of the medical tube include a medical catheter, a manipulator, and a lead.

The silicone rubber of the present embodiment can constitute, for example, a part of a drive mechanism such as a joint; a wiring mechanism such as a wiring cable and a connector; an operation mechanism such as a manipulator, which are examples of the robot applications such as an industrial robot.

The silicone rubber of the present embodiment can constitute, for example, apart of a stretchable interconnect or wiring substrate, used for a wearable device which can be worn on a human body and the like; cables such as an optical fiber, a flat cable, a wiring structure, and a cable guide; and sensors such as a touch panel, a force sensor, an MEMS, and a seat sensor, which are examples of the electronic equipment applications.

In addition, the silicone rubber of the present embodiment can constitute a part of daily commodities having flexibility, extensibility, or foldability, such as packaging materials such as a gas barrier film; cooking utensils; hoses; fixing belts; switches; sheet materials; and packing materials.

The respective components of the silicone rubber-based curable composition of the present embodiment will be described in detail.

<<Vinyl Group-Containing Organopolysiloxane (A))>>

The silicone rubber-based curable composition of the present embodiment includes a vinyl group-containing organopolysiloxane (A).

The vinyl group-containing organopolysiloxane (A) is a polymerization product that is a main component of the silicone rubber-based curable composition.

The vinyl group-containing organopolysiloxane (A) can include a vinyl group-containing linear organopolysiloxane (A1) having a linear structure.

The vinyl group-containing linear organopolysiloxane (A1) has a linear structure and contains a vinyl group, and the vinyl group serves as a crosslinking point during curing.

The content of vinyl groups of the vinyl group-containing linear organopolysiloxane (A1) is not particularly limited but, for example, two or more vinyl groups are contained in the molecule and the content of vinyl groups is preferably equal to or less than 15% by mole, and more preferably 0.01% to 12% by mole. Thus, the amount of vinyl groups in the vinyl group-containing linear organopolysiloxane (A1) is optimized, and a network with the respective components which will be described later can be reliably formed.

In the present specification, the content of vinyl groups is an amount in % by mole of the vinyl group-containing siloxane units in a case where all the units constituting the vinyl group-containing linear organopolysiloxane (A1) are taken as 100% by mole. It should be noted that it is considered that one vinyl group is used with respect to one vinyl group-containing siloxane unit.

The degree of polymerization of the vinyl group-containing linear organopolysiloxane (A1) is not particularly limited, but is, for example, preferably in the range of about 1,000 to 10,000, and more preferably in the range of about 2,000 to 5,000.

Furthermore, the degree of polymerization may be calculated from a number-average molecular weight.

In addition, the weight-average molecular weight Mw of the vinyl group-containing linear organopolysiloxane (A1) may be, for example, 5.0×10⁴ to equal to or less than 1.0×10⁶, preferably 1.0×10⁵ to 9.0×10⁵, and more preferably 3.0×10⁵ to 8.0×10⁵.

The weight-average molecular weight (Mw)/the number-average molecular weight (Mn) of the vinyl group-containing linear organopolysiloxane (A1) may be, for example, equal to or more than 1.5 and equal to or less than 4.0, preferably equal to or more than 1.8 and equal to or less than 3.5, and more preferably equal to or more than 2.0 and equal to or less than 2.8. Furthermore, Mw/Mn is a dispersity indicating the width of a molecular weight distribution.

The weight-average molecular weight and the number-average molecular weight can be measured, for example, in terms of polystyrene in gel permeation chromatography (GPC) using chloroform as a developing solvent.

The specific gravity of the vinyl group-containing linear organopolysiloxane (A1) is not particularly limited, but is preferably in the range of about 0.9 to 1.1.

By using those having a degree of polymerization and a specific gravity, each in the ranges, as the vinyl group-containing linear organopolysiloxane (A1), the improvement of the heat resistance, the flame retardancy, the chemical stability, and the like of the obtained silicone rubber can be promoted.

The vinyl group-containing linear organopolysiloxane (A1) is particularly preferably one having a structure represented by Formula (1).

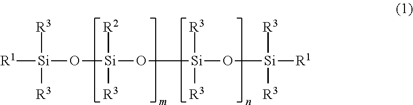

In Formula (1), R¹ is a substituted or unsubstituted alkyl group, alkenyl group, or aryl group having 1 to 10 carbon atoms, or a hydrocarbon group formed by the combination of these groups. Examples of the alkyl group having 1 to 10 carbon atoms include a methyl group, an ethyl group, and a propyl group, and among these, the methyl group is preferable. Examples of the alkenyl group having 1 to 10 carbon atoms include a vinyl group, an allyl group, a butenyl group, and among these, the vinyl group is preferable. Examples of the aryl group having 1 to 10 carbon atoms include a phenyl group.

In Formula (1), R² is a substituted or unsubstituted alkyl group, alkenyl group, or aryl group having 1 to 10 carbon atoms, or a hydrocarbon group formed by the combination of these groups. Examples of the alkyl group having 1 to 10 carbon atoms include a methyl group, an ethyl group, and a propyl group, and among these, the methyl group is preferable. Examples of the alkenyl group having 1 to 10 carbon atoms include a vinyl group, an allyl group, and a butenyl group. Examples of the aryl group having 1 to 10 carbon atoms include a phenyl group.

In Formula (1), R³ is a substituted or unsubstituted alkyl group or aryl group having 1 to 8 carbon atoms, or a hydrocarbon group formed by the combination of these groups. Examples of the alkyl group having 1 to 8 carbon atoms include a methyl group, an ethyl group, and a propyl group, and among these, the methyl group is preferable. Examples of the aryl group having 1 to 8 carbon atoms include a phenyl group.

In addition, examples of the substituent of R¹ and R² in Formula (1) include a methyl group and a vinyl group, and examples of the substituent of R³ include a methyl group.

Furthermore, in Formula (1), a plurality of R¹'s are independent of each other, and may be the same as or different from each other. Further, this shall apply to R² and R³. In addition, in Formula (1), at least one of the plurality of R¹'s and R²'s is an alkenyl group.

Furthermore, m and n are each the number of repeating units constituting the vinyl group-containing linear organopolysiloxane (A1) represented by Formula (1), m is an integer of 0 to 2,000, and n is an integer of 1,000 to 10,000. m is preferably 0 to 1,000, and n is preferably 2,000 to 5,000. Moreover, m+n is, for example, an integer of equal to or more than 1,000.

m and n each represent a degree of polymerization calculated using the number-average molecular weight Mn.

Moreover, examples of the specific structure of the vinyl group-containing linear organopolysiloxane (A1) represented by Formula (1) include one represented by Formula (1-1).

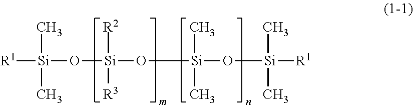

In Formula (1-1), R¹ and R² are each independently a methyl group or a vinyl group, and at least one of R¹ and R² is the vinyl group.

In the present specification, the vinyl group-containing linear organopolysiloxane (A1) in which only R¹ (terminal) is a vinyl group in the structure represented by Formula (1-1) is denoted as (A1-1), and the vinyl group-containing linear organopolysiloxane (A1) in which only R¹ (terminal) and R² (in the chain) are vinyl groups in the structure represented by Formula (1-1) is denoted as (A1-2).

As the vinyl group-containing linear organopolysiloxane (A1), those in which two or more vinyl groups are contained in the molecule and the content of vinyl groups is equal to or less than 15% by mole, are preferable. The amount of vinyl groups of the vinyl group-containing linear organopolysiloxane (A1) may be, for example, equal to or less than 0.4% by mole, preferably equal to or less than 0.3% by mole, equal to or less than 0.2% by mole, equal to or less than 0.1% by mole, or equal to or less than 0.08% by mole. By using the vinyl group-containing linear organopolysiloxane (A1), having a general content of vinyl groups, as a raw rubber which is a raw material of a silicone rubber, coarseness-and-fineness of the crosslinking density of the silicone rubber can be more effectively formed in a crosslinked network of the silicone rubber. As a result, the tear strength of the silicone rubber can be more effectively reliably enhanced.

It is preferable that the vinyl group-containing linear organopolysiloxane (A1) includes a first vinyl group-containing linear organopolysiloxane (A1-1), in which two or more vinyl groups are contained in the molecule and the content of vinyl groups is equal to or less than 0.1% by mole.

In addition, as the vinyl group-containing linear organopolysiloxane (A1), the first vinyl group-containing linear organopolysiloxane (A1-1), in which two or more vinyl groups are contained in the molecule and the content of vinyl groups is equal to or less than 0.1% by mole, may be used alone, but a combination of two or more kinds including a second vinyl group-containing linear organopolysiloxane (A1-2), in which the content of vinyl groups is more than 0.1% by mole to 15% by mole, and the like, may also be used.

<<Organohydrogenpolysiloxane (B)>>

The silicone rubber-based curable composition of the present embodiment may include an organohydrogenpolysiloxane (B).

The organohydrogenpolysiloxane (B) is classified into a linear organohydrogenpolysiloxane (B1) having a linear structure and a branched organohydrogenpolysiloxane (B2) having a branched structure, and either one or both thereof can be included.

The linear organohydrogenpolysiloxane (B1) is a polymer which has a linear structure, further has a structure in which hydrogen is directly bonded to Si (≡Si—H), and undergoes a hydrosilylation reaction with a vinyl group contained in the components to be blended in the silicone rubber-based curable composition, other than the vinyl group of the vinyl group-containing organopolysiloxane (A), thereby crosslinking these components.

The molecular weight of the linear organohydrogenpolysiloxane (B1) is not particularly limited but, for example, the weight-average molecular weight is preferably equal to or less than 20,000, and more preferably equal to or more than 1,000 and equal to or less than 10,000.

Furthermore, the weight-average molecular weight of the linear organohydrogenpolysiloxane (B1) can be measured, for example, in terms of polystyrene in gel permeation chromatography (GPC) using chloroform as a developing solvent.

In addition, it is typically preferable that the linear organohydrogenpolysiloxane (B1) has no vinyl group. Thus, the progress of a crosslinking reaction in the molecule of the linear organohydrogenpolysiloxane (B1) can be reliably prevented.

As such a linear organohydrogenpolysiloxane (B1), for example, one having a structure represented by Formula (2) is preferably used.

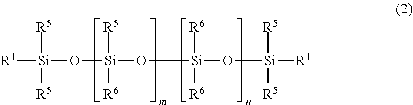

In Formula (2), R⁴ is a substituted or unsubstituted alkyl group, alkenyl group, or aryl group having 1 to 10 carbon atoms, a hydrocarbon group formed by the combination of these groups, or a hydride group. Examples of the alkyl group having 1 to 10 carbon atoms include a methyl group, an ethyl group, and a propyl group, and among these, the methyl group is preferable. Examples of the alkenyl group having 1 to 10 carbon atoms include a vinyl group, an allyl group, and a butenyl group. Examples of the aryl group having 1 to 10 carbon atoms include a phenyl group.

In addition, R⁵ is a substituted or unsubstituted alkyl group, alkenyl group, or aryl group having 1 to 10 carbon atoms, a hydrocarbon group formed by the combination of these groups, or a hydride group. Examples of the alkyl group having 1 to 10 carbon atoms include a methyl group, an ethyl group, and a propyl group, and among these, the methyl group is preferable. Examples of the alkenyl group having 1 to 10 carbon atoms include a vinyl group, an allyl group, and a butenyl group. Examples of the aryl group having 1 to 10 carbon atoms include a phenyl group.

Furthermore, in Formula (2), a plurality of R⁴'s are independent of each other, and may be the same as or different from each other. This shall apply to R⁵. It should be noted that at least two or more of the plurality of R⁴'s and R⁵'s are hydride groups.

In addition, R⁶ is a substituted or unsubstituted alkyl group or aryl group having 1 to 8 carbon atoms, or a hydrocarbon group formed by the combination of these groups. Examples of the alkyl group having 1 to 8 carbon atoms include a methyl group, an ethyl group, and a propyl group, and among these, the methyl group is preferable. Examples of the aryl group having 1 to 8 carbon atoms include a phenyl group. A plurality of R⁶'s are independent of each other, and may be the same as or different from each other.

Furthermore, examples of the substituent of R⁴, R⁵, and R⁶ in Formula (2) include a methyl group and a vinyl group, and the methyl group is preferable from the viewpoint that the crosslinking reaction in the molecule is prevented.

In addition, m and n are each the number of repeating units constituting the linear organohydrogenpolysiloxane (B1) represented by Formula (2), m is an integer of 2 to 150, and n is an integer of 2 to 150. Preferably, m is an integer of 2 to 100 and n is an integer of 2 to 100.

Furthermore, the linear organohydrogenpolysiloxane (B1) may be used alone or in combination of two or more kinds thereof.

The branched organohydrogenpolysiloxane (B2) is a component which forms an area having a high crosslinking density due to its branched structure, and thus greatly contributes to formation of coarse-and-fine structure of a crosslinking density in a system of a silicone rubber. In addition, the branched organohydrogenpolysiloxane (B2) is a polymer which has a structure in which hydrogen is directly bonded to Si(Si—H), and undergoes a hydrosilylation reaction with a vinyl group of the components to be blended in the silicone rubber-based curable composition, other than the vinyl group of the vinyl group-containing organopolysiloxane (A), thereby crosslinking these components, in the same manner as the linear organohydrogenpolysiloxane (B1).

In addition, the specific gravity of the branched organohydrogenpolysiloxane (B2) is in the range of 0.9 to 0.95.

Further, it is typically preferable that the branched organohydrogenpolysiloxane (B2) has no vinyl group. Thus, the progress of a crosslinking reaction in the molecule of the branched organohydrogenpolysiloxane (B2) can be reliably prevented.

In addition, as the branched organohydrogenpolysiloxane (B2), one represented by the following Average Composition Formula (c) is preferable.

(Hₐ(R⁷)₃₋ₐSiO_{1/2})ₘ(SiO_{4/2})ₙ Average Composition Formula (c)

(In Formula (c), R⁷ is a monovalent organic group, a is an integer in the range of 1 to 3, m is the number of Hₐ (R⁷)₃₋ₐSiO_{1/2} units, and n is the number of SiO_{4/2} units.)

In Formula (c), R⁷ is a monovalent organic group, preferably a substituted or unsubstituted alkyl group or aryl group having 1 to 10 carbon atoms, or a hydrocarbon group formed by the combination of these groups. Examples of the alkyl group having 1 to 10 carbon atoms include a methyl group, an ethyl group, and a propyl group, and among these, the methyl group is preferable. Examples of the aryl group having 1 to 10 carbon atoms include a phenyl group.

In Formula (c), a is the number of hydride groups (hydrogen atoms directly bonded to Si), and is an integer in the range of 1 to 3, and preferably 1.

In addition, in Formula (c), m is the number of Hₐ (R⁷)₃₋ₐSiO_{1/2} units, and n is the number of SiO_{4/2} units.

The branched organohydrogenpolysiloxane (B2) has a branched structure. The linear organohydrogenpolysiloxane (B1) and the branched organohydrogenpolysiloxane (B2) are different in that the structures are linear and branched, respectively, and in a case where the number of Si is 1, the number of the alkyl groups R's bonded to Si (R/Si) is 1.8 to 2.1 for the linear organohydrogenpolysiloxane (B1) or 0.8 to 1.7 for the branched organohydrogenpolysiloxane (B2).

Moreover, since the branched organohydrogenpolysiloxane (B2) has a branched structure, the amount of residues in a case of heating to 1,000° C. at a temperature rising rate of 10° C./minute in a nitrogen atmosphere, for example, is equal to or more than 5%. On the other hand, since the linear organohydrogenpolysiloxane (B1) is linear, the amount of the residues after heating under the conditions is almost zero.

Moreover, specific examples of the branched organohydrogenpolysiloxane (B2) include one having a structure represented by Formula (3).

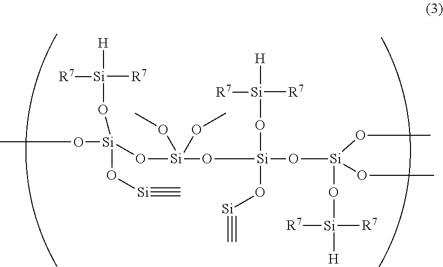

In Formula (3), R⁷ is a substituted or unsubstituted alkyl group or aryl group having 1 to 8 carbon atoms, or a hydrocarbon group formed by the combination of these groups, or a hydrogen atom. Examples of the alkyl group having 1 to 8 carbon atoms include a methyl group, an ethyl group, and a propyl group, and among these, the methyl group is preferable. Examples of the aryl group having 1 to 8 carbon atoms include a phenyl group. Examples of the substituent of R⁷ include a methyl group.

Furthermore, in Formula (3), a plurality of R⁷'s are independent of each other, and may be the same as or different from each other.

In addition, in Formula (3), “—O—Si≡” denotes inclusion of a branched structure in which Si is diffused three-dimensionally.

Furthermore, the branched organohydrogenpolysiloxane (B2) may be used alone or in combination of two or more kinds thereof.

In addition, in the linear organohydrogenpolysiloxane (B1) and the branched organohydrogenpolysiloxane (B2), the amount of the hydrogen atoms (hydride groups) directly bonded to Si is not particularly limited. It should be noted that in the silicone rubber-based curable composition, the total amount of the hydride groups in the linear organohydrogenpolysiloxane (B1) and the branched organohydrogenpolysiloxane (B2) is preferably 0.5 to 5 moles, and more preferably 1 to 3.5 moles, with respect to one mole of the vinyl groups in the vinyl group-containing linear organopolysiloxane (A1). Thus, a crosslinked network among the linear organohydrogenpolysiloxane (B1), the branched organohydrogenpolysiloxane (B2), and the vinyl group-containing linear organopolysiloxane (A1) can be reliably formed.

<<Silica Particles (C)>>

The silicone rubber-based curable composition of the present embodiment include silica particles (C).

The silica particles (C) are not particularly limited but, for example, fumed silica, calcined silica, precipitated silica, or the like is used. These may be used alone or in combination of two or more kinds thereof. The silica particles (C) may include one or more silica particles which have been surface-treated with the silane coupling agent (D).

The silica particles (C) have, for example, a specific surface area according to the BET method of 200 m²/g to 500 m²/g, preferably 220 m²/g to 400 m²/g, and more preferably 250 m²/g to 400 m²/g.

In addition, the average primary particle diameter of the silica particles (C) is, for example, preferably 1 to 100 nm, and more preferably about 5 to 20 nm.

By using the silica particles (C) having the specific surface area and the average particle diameter in those ranges, the hardness and the mechanical strength, in particular, the tensile strength of the formed silicone rubber can be improved.

<<Silane Coupling Agent (D)>>

The silicone rubber-based curable composition of the present embodiment may include a silane coupling agent (D).

The silane coupling agent (D) can have a hydrolyzable group. The hydrolyzable group is hydrolyzed with water to turn into a hydroxyl group, and the hydroxyl group undergoes a dehydrative condensation reaction with the hydroxyl group on a surface of the silica particles (C) to carry out the surface modification of the silica particles (C).

The silane coupling agent (D) can include a silane coupling agent having a hydrophobic group. As the silane coupling agent having a hydrophobic group, a silane coupling agent having a trimethylsilyl group can be used. Thus, since the hydrophobic group is provided on a surface of the silica particles (C), the aggregation force of the silica particles (C) is reduced (aggregation by hydrogen bonding due to silanol groups is reduced) in the silicone rubber-based curable composition and also in the silicone rubber, and as a result, it is presumed that the dispersibility of the silica particles in the silicone rubber-based curable composition is improved. Thus, an interface between the silica particles and the rubber matrix is increased and the reinforcing effect of the silica particles is enhanced. Further, it is presumed that the slip properties of the silica particles in the matrix are improved in a case of matrix modification of the rubber. In addition, due to the improvement of the dispersibility of the silica particles and the improvement of the slip properties, the mechanical strength (for example, a tensile strength and a tear strength) of the silicone rubber due to the silica particles is improved.

Moreover, the silane coupling agent (D) can include a silane coupling agent having a vinyl group. Thus, the vinyl group is introduced onto a surface of the silica particles (C). Therefore, in a case where the vinyl group contained in the silica particles (C) is also involved in a crosslinking reaction during formation of a network (crosslinked structure) while the silicone rubber-based curable composition is cured, and accordingly, the silica particles (C) are also captured in the network. Thus, it is possible to promote a decrease in a hardness and an increased in a modulus of a silicone rubber thus formed.

As the silane coupling agent (D), a silane coupling agent having a hydrophobic group and a silane coupling agent having a vinyl group can be used in combination. Thus, it is possible to promote a balance in the dispersibility of silica in the rubber and the crosslinkability of the rubber. The silane coupling agent (D) may be used alone or in combination of two or more kinds thereof.

Examples of the silane coupling agent (D) include one represented by Formula (4).

Yₙ—Si—(X)₄₋ₙ (4)

In Formula (4), n represents an integer of 1 to 3. Y represents any functional group having a hydrophobic group, a hydrophilic group, or a vinyl group, and in a case where n is 1, Y is the hydrophobic group, and in a case where n is 2 or 3, at least one of Y's is the hydrophobic group. X represents a hydrolyzable group.

The hydrophobic group is an alkyl group or aryl group having 1 to 6 carbon atoms, or a hydrocarbon group formed by the combination of these groups, examples thereof include a methyl group, an ethyl group, a propyl group, and a phenyl group, and the methyl group is preferable.

Examples of the hydrophilic group include a hydroxyl group, a sulfonic acid group, a carboxyl group, and a carbonyl group, and among these, the hydroxyl group is particularly preferable. Furthermore, the hydrophilic group may be included as a functional group, but is not preferably included from the viewpoint of imparting hydrophobicity to the silane coupling agent (D).

Moreover, examples of the hydrolyzable group include alkoxy groups such as a methoxy group and an ethoxy group, a chloro group, and a silazane group, and among these, the silazane group is preferable from the viewpoint of its high reactivity with the silica particles (C). Further, inclusion of the silazane group as the hydrolyzable group means inclusion of two structures of (Yₙ—Si—) in Formula (4) from the structural characteristics.

Specific examples of the silane coupling agent (D) represented by Formula (4) are as follows.

Those having a hydrophobic group as a functional group, for example, alkoxysilanes such as methyltrimethoxysilane, dimethyldimethoxysilane, phenyltrimethoxysilane, methyltriethoxysilane, dimethyldiethoxysilane, phenyltriethoxysilane, n-propyltrimethoxysilane, n-propyltriethoxysilane, hexyltrimethoxysilane, hexyltriethoxysilane, and decyltrimethoxysilane; chlorosilanes such as methyltrichlorosilane, dimethyldichlorosilane, trimethylchlorosilane, and phenyltrichlorosilane; and hexamethyldisilazane. Among these, the silane coupling agent having a trimethylsilyl group including at least one selected from the group consisting of hexamethyldisilazane, trimethylchlorosilane, trimethylmethoxysilane, and trimethylethoxysilane is preferable.

Those having a vinyl group as a functional group, for example, alkoxysilanes such as methacryloxypropyltriethoxysilane, methacryloxypropyltrimethoxysilane, methacryloxypropylmethyldiethoxysilane, methacryloxypropylmethyldimethoxysilane, vinyltriethoxysilane, vinyltrimethoxysilane, and vinylmethyldimethoxysilane; chlorosilanes such as vinyltrichlorosilane, and vinylmethyldichlorosilane; and divinyltetramethyldisilazane. Among these, the silane coupling agent having a vinyl group-containing organosilyl group including at least one selected from the group consisting of methacryloxypropyltriethoxysilane, methacryloxypropyltrimethoxysilane, methacryloxypropylmethyldiethoxysilane, methacryloxypropylmethyldimethoxysilane, divinyltetramethyldisilazane, vinyltriethoxysilane, vinyltrimethoxysilane, and vinylmethyldimethoxysilane is preferable.

In addition, in a case where the silane coupling agent (D) includes two kinds of silane coupling agents, that is, a silane coupling agent having a trimethylsilyl group and a silane coupling agent having a vinyl group-containing organosilyl group, hexamethyldisilazane is preferable as the silane coupling agent having a hydrophobic group; and divinyltetramethyldisilazane is preferable as the silane coupling agent having a vinyl group.

In a case where a silane coupling agent (D1) having a trimethylsilyl group and a silane coupling agent (D2) having a vinyl group-containing organosilyl group are used in combination, a ratio of (D1) to (D2) is not particularly limited, but the ratio (D1): (D2) in terms of weight is, for example, 1:0.001 to 1:0.35, preferably 1:0.01 to 1:0.20, and more preferably 1:0.03 to 1:0.15. By setting the ratio to such a numerical range, it is possible to obtain desired silicone rubber physical properties in the silicone rubber. Specifically, it is possible to promote a balance in the dispersibility of silica in the rubber and the crosslinkability of the rubber.

<<Platinum or Platinum Compound (E)>>

The silicone rubber-based curable composition of the present embodiment may include platinum or platinum compound (E).

The platinum or platinum compound (E) is a catalytic component that acts as a catalyst during curing. The amount of the platinum or platinum compound (E) to be added is a catalytic amount.

As the platinum or platinum compound (E), known ones can be used, and examples thereof include platinum black, those having platinum supported on silica, carbon black, or the like, chloroplatinic acid or an alcohol solution of chloroplatinic acid, a complex salt of chloroplatinic acid with an olefin, and a complex salt of chloroplatinic acid with vinyl siloxane.

Furthermore, the platinum or platinum compound (E) may be used alone or in combination of two or more kinds thereof.

Moreover, the silicone rubber-based curable composition of the present embodiment may include an organic peroxide (H).

The organic peroxide (H) is a component that acts as a catalyst during curing. The amount of the organic peroxide (H) to be added is a catalytic amount. The organic peroxide (H) can be used instead of the organohydrogenpolysiloxane (B) and the platinum or platinum compound (E), or the organohydrogenpolysiloxane (B) and the platinum or platinum compound (E) can be used in combination with the organic peroxide (H).

Examples of the organic peroxide (H) include ketone peroxides, diacyl peroxides, hydroperoxides, dialkyl peroxides, peroxyketals, alkyl peresters, peroxyesters, and peroxydicarbonates, and specific examples thereof include benzoyl peroxide, 2,4-dichlorobenzoyl peroxide, p-methylbenzoyl peroxide, o-methylbenzoyl peroxide, dicumyl peroxide, 2,5-dimethyl-bis(2,5-t-butylperoxy)hexane, di-t-butyl peroxide, t-butyl perbenzoate, and 1,6-hexanediol-bis-t-butylperoxycarbonate.

<<Water (F)>>

Moreover, the silicone rubber-based curable composition of the present embodiment may include water (F), in addition to the components (A) to (E) and (H).

Water (F) is a component that functions as a dispersion medium for dispersing the respective components included in the silicone rubber-based curable composition and contributes to a reaction between the silica particles (C) and the silane coupling agent (D). Therefore, in the silicone rubber, the silica particles (C) and the silane coupling agent (D) can be more reliably linked to each other, which can thus exert exhibit uniform characteristics as a whole.

Furthermore, the silicone rubber-based curable composition of the present embodiment may contain known components to be blended in the silicone rubber-based curable composition, in addition to the components (A) to (F). Examples of the known components include diatomaceous earth, iron oxide, zinc oxide, titanium oxide, barium oxide, magnesium oxide, cerium oxide, calcium carbonate, magnesium carbonate, zinc carbonate, glass wool, and mica. In addition, a dispersing agent, a pigment, a dye, an antistatic agent, an antioxidant, a flame retardant, a thermal conductivity enhancing agent, or the like can be appropriately blended.

In addition, the content of each of the components in the silicone rubber-based curable composition is not particularly limited, but is set in the following manner, for example.

In the present embodiment, the upper limit of the content of the silica particles (C) may be, for example, equal to or less than 60 parts by weight, preferably equal to or less than 50 parts by weight, and more preferably equal to or less than 35 parts by weight, with respect to 100 parts by weight of the total amount of the vinyl group-containing organopolysiloxane (A). Thus, it is possible to promote a balance a mechanical strength such as a hardness and a tensile strength. In addition, the lower limit of the content of the silica particles (C) is not particularly limited, but may be, for example, equal to or more than 10 parts by weight with respect to 100 parts by weight of the total amount of the vinyl group-containing organopolysiloxane (A).

The silane coupling agent (D) is contained, for example, in a proportion of preferably equal to or more than 5 parts by weight and equal to or less than 100 parts by weight, more preferably in a proportion of equal to or more than 5 parts by weight and equal to or less than 40 parts by weight, with respect to 100 parts by weight of the vinyl group-containing organopolysiloxane (A). Thus, the dispersibility of the silica particles (C) in the silicone rubber-based curable composition can be reliably improved.

The content of the organohydrogenpolysiloxane (B) is, for example, preferably equal to or more than 0.5 part by weight and equal to or less than 20 parts by weight, and more preferably equal to or more than 0.8 parts by weight and equal to or less than 15 parts by weight, with respect to 100 parts by weight of the total amount of the vinyl group-containing organopolysiloxane (A), the silica particles (C), and the silane coupling agent (D). In a case where the content of (B) is within the range, there is a possibility that a more effective curing reaction proceeds.

The content of the platinum or platinum compound (E) means a catalytic amount and can be appropriately set, but is specifically an amount such that the amount of the platinum group metal in the present component is 0.01 to 1,000 ppm, and preferably 0.1 to 500 ppm, with respect to 100 parts by weight of the total amount of the vinyl group-containing organopolysiloxane (A), the silica particles (C), and the silane coupling agent (D). By setting the content of the platinum or platinum compound (E) to equal to or more than the lower limit, the obtained silicone rubber composition can be sufficiently cured. By setting the content of the platinum or platinum compound (E) to equal to or less than the upper limit, the curing rate of the obtained silicone rubber composition can be improved.

The content of the organic peroxide (H) means a catalytic amount and can be appropriately set, but is specifically, for example, an amount such that the amount of the platinum group metal in this component is equal to or more than 0.001 part by weight, preferably equal to or more than 0.005 part by weight, and more preferably equal to or more than 0.01 part by weight, with respect to 100 parts by weight of the total amount of the vinyl group-containing organopolysiloxane (A), the silica particles (C), and the silane coupling agent (D). Thus, the minimum strength as a cured product can be secured. In addition, the upper limit of the content of the organic peroxide (H) is, for example, equal to or less than 10 parts by weight, preferably equal to or less than 5 parts by weight, and more preferably equal to or less than 3 parts by weight, with respect to 100 parts by weight of the total amount of the vinyl group-containing organopolysiloxane (A), the silica particles (C), and the silane coupling agent (D). Thus, the influence of by-products can be suppressed.

Furthermore, in a case where water (F) is contained, a content thereof can be appropriately set, but is specifically, for example, preferably in the range of 10 to 100 parts by weight, and more preferably in the range of 30 to 70 parts by weight, with respect to 100 parts by weight of the silane coupling agent (D). Thus, the progress of a reaction between the silane coupling agent (D) and the silica particles (C) can be more reliably made.

<Method for Manufacturing Silicone Rubber>

Next, the method for manufacturing a silicone rubber of the present embodiment will be described.

In the method for manufacturing a silicone rubber of the present embodiment, a silicone rubber can be obtained by preparing a silicone rubber-based curable composition and curing the silicone rubber-based curable composition.

Details thereof will be described below.

First, the respective components of the silicone rubber-based curable composition are uniformly mixed by any kneading apparatus to prepare a silicone rubber-based curable composition.

[1] For example, the vinyl group-containing organopolysiloxane (A), the silica particles (C), and the silane coupling agent (D) are weighed to predetermined amounts and then kneaded using any kneading apparatus, thereby obtaining a kneaded product containing each of these components (A), (C), and (D).

Furthermore, the kneaded product is preferably obtained by kneading the vinyl group-containing organopolysiloxane (A) and the silane coupling agent (D) in advance, and then kneading (mixing) the silica particles (C) therewith. Thus, the dispersibility of the silica particles (C) in the vinyl group-containing organopolysiloxane (A) is further improved.

In addition, in a case of obtaining the kneaded product, water (F) may be added to the kneaded product of the respective components (A), (C), and (D) as needed. Thus, the progress of a reaction between the silane coupling agent (D) and the silica particles (C) can be more reliably made.

In addition, it is preferable to knead the respective components (A), (C), and (D)) by conducting a first step of heating the components to a first temperature and a second step of heating the components to a second temperature. Thus, in the first step, the silica particles (C) can be surface-treated with the coupling agent (D), and in the second step, by-products that are produced in the reaction between the silica particles (C) and the coupling agent (D) can be reliably removed from the kneaded product. Then, the component (A) may be added to the obtained kneaded product and further kneaded as needed. Thus, the fitting among the components of the kneaded product can be improved.

The first temperature is preferably, for example, about 40° C. to 120° C., and more preferably, for example, about 60° C. to 90° C. The second temperature is preferably, for example, about 130° C. to 210° C., and more preferably, for example, about 160° C. to 180° C.

In addition, the atmosphere in the first step is preferably an inert atmosphere such as a nitrogen atmosphere, and the atmosphere in the second step is preferably an atmosphere under reduced pressure.

Further, the time in the first step is preferably, for example, about 0.3 to 1.5 hours, and more preferably about 0.5 to 1.2 hours. The time in the second step is, for example, preferably about 0.7 to 3.0 hours, and more preferably about 1.0 to 2.0 hours.

By conducting the first step and the second step under the same conditions as above, the effect can be obtained more remarkably.

[2] Next, the organohydrogenpolysiloxane (B) and the platinum or platinum compound (E) are weighed to predetermined amounts, and then the kneaded product prepared in the step [1] is kneaded with the respective components (B) and (E) using any kneading apparatus, thereby obtaining a silicone rubber-based curable composition. The obtained silicone rubber-based curable composition may be a paste including a solvent.

Furthermore, in a case where the respective components (B) and (E) are kneaded, it is preferable to knead the organohydrogenpolysiloxane (B) with the kneaded product prepared in the step [1] and knead the platinum or platinum compound (E) with the kneaded product prepared in the step [1] in advance; and then knead the respective kneaded products. Thus, the respective components (A) to (E) can be reliably dispersed in the silicone rubber-based curable composition without the progress of the reaction between the vinyl group-containing organopolysiloxane (A) and the organohydrogenpolysiloxane (B).

The temperature at which the respective components (B) and (E) are kneaded, which is a roll setting temperature, is preferably about 10° C. to 70° C., and more preferably about 25° C. to 30° C.

In addition, the kneading time is preferably about 5 minutes to 1 hour, and more preferably about 10 to 40 minutes.

By setting the temperature within the range in the steps [1] and [2], the progress of the reaction between the vinyl group-containing organopolysiloxane (A) and the organohydrogenpolysiloxane (B) can be more reliably prevented or suppressed. In addition, by setting the kneading time within the range in the steps [1] and [2], the respective components (A) to (E) can be more reliably dispersed in the silicone rubber-based curable composition.

Furthermore, the kneading apparatus used in each of the steps [1] and [2] is not particularly limited but, for example, a kneader, two rolls, a Banbury mixer (continuous kneader), a pressurization kneader, or the like can be used.

In addition, a reaction inhibitor such as 1-ethynylcyclohexanol may be added to the kneaded product in the present step [2]. Thus, even in a case where the temperature of the kneaded product is set to a relatively high temperature, the progress of the reaction between the vinyl group-containing organopolysiloxane (A) and the organohydrogenpolysiloxane (B) can be more reliably prevented or suppressed.

In addition, in the present step [2], the organic peroxide (H) may be added instead of the organohydrogenpolysiloxane (B) and the platinum or the platinum compound (E), or in combination with the organohydrogenpolysiloxane (B) and the platinum or the platinum compound (E). Preferred conditions such as a temperature and a time during the kneading of the organic peroxide (H), and a device to be used are the same as those with the conditions for kneading the organohydrogenpolysiloxane (B) and the platinum or platinum compound (E).

[3] Next, a silicone rubber is formed by curing the silicone rubber-based curable composition.

In the present embodiment, the curing step of the silicone rubber-based curable composition is conducted by, for example, heating at 100° C. to 250° C. for 1 to 30 minutes (primary curing) and then post-baking at 200° C. for 1 to 4 hours (secondary curing).

By conducting the steps as described above, the silicone rubber (cured product of silicone rubber-based curable composition) of the present embodiment can be obtained.

The method for manufacturing a structure of the present embodiment may be configured to have a step of curing the silicone rubber-based curable composition and a step of obtaining a structure including a cured product of the silicone rubber-based curable composition.

In the step of obtaining such a structure, the structure may be the wearable device.

Although the embodiments of the present invention have been described above, these are examples of the present invention and various configurations other than those can be adopted. In addition, the present invention is not limited to the above-described embodiments, and modifications, improvements, and the like within a scope in which the object of the present invention can be accomplished are included in the present invention.

Hereinafter, examples of reference forms will be added.

1. A silicone rubber-based curable composition including:

a vinyl group-containing organopolysiloxane (A), and

silica particles (C),

in which in a case where a De Mattia-type bending resistance test in accordance with JIS K 6260 is performed using a test piece formed of a cured product of the silicone rubber-based curable composition, a ratio (L₅/L₀) of change in a cut length in the test piece with the number of times of bending of 50,000 is equal to or more than 1.1 and equal to or less than 11.5, the ratio being measured on the basis of the following procedure.

(Procedure)

The silicone rubber-based curable composition is pressed at 170° C. and 10 MPa for 15 minutes, and subsequently heated at 200° C. for 4 hours to manufacture a test piece having a predetermined shape in accordance with JIS K 6260.

In the center of the obtained test piece, a cut having a predetermined length penetrating the test piece is formed in parallel to a width direction. The initial cut length is defined as L₀.

Subsequently, the test piece with the cut is attached between grippers of a tester, the De Mattia-type bending resistance test is performed based on the following test conditions, and a cut length (mm) in the test piece after a predetermined number of times of bending is measured.

An average value in a case where the De Mattia-type bending resistance test is performed three times is used as the cut length. The average value of the cut length is defined as L₅.

The ratio of change in the cut length is calculated based on an expression: L₅/L₀.

(Test Conditions)
Test standard: In accordance with JIS K 6260
Tester: De Mattia bending-cracking tester
Test temperature: 23±2° C.
Maximum distance between grippers: 75 mm
Reciprocating distance: 57 mm
Test speed: 300±10 times/minute
Number of tests: n=3

2. The silicone rubber-based curable composition as described in 1.,

in which in a case where the De Mattia-type bending resistance test based on the procedure is performed and a cut length in the test piece with the number of times of bending of 10,000 is defined as L₁, L₁/L₀ satisfies a range of equal to or more than 1.0 and equal to or less than 10.0.

3. The silicone rubber-based curable composition as described in 1. or 2.,

in which a content of the silica particles (C) is equal to or more than 10 parts by weight and equal to or less than 35 parts by weight with respect to a total of 100 parts by weight of the vinyl group-containing organopolysiloxane (A).

4. The silicone rubber-based curable composition as described in any one of 1. to 3.,

in which a tear strength of the silicone rubber-based curable composition, as measured under the following conditions, is equal to or more than 25 N/mm.

(Measurement Conditions for Tear Strength)

A crescent-shaped test piece is manufactured using a cured product of the silicone rubber-based curable composition, and for the obtained crescent-shaped test piece, a tear strength is measured at 25° C. in accordance with JIS K 6252 (2001).

5. The silicone rubber-based curable composition as described in any one of 1. to 4.,

in which an elongation at break of a cured product of the silicone rubber-based curable composition, as measured under the following conditions, is equal to or more than 500%.

(Measurement Conditions for Elongation at Break)

A dumbbell-shaped type-3 test piece is manufactured in accordance with JIS K 6251 (2004), using the cured product of the silicone rubber-based curable composition, and an elongation at break of the obtained dumbbell-shaped type-3 test piece is measured at 25° C. The elongation at break is calculated by [Moving distance (mm) between chucks]=[Initial distance (60 mm) between chucks]×100. The unit is %.

6. The silicone rubber-based curable composition as described in any one of 1. to 5.,

in which a durometer hardness A of a cured product of the silicone rubber-based curable composition, as measured under the following conditions, is equal to or more than 10 and equal to or less than 70.

(Measurement Conditions for Durometer Hardness A)

A sheet-shaped test piece is manufactured using the cured product of the silicone rubber-based curable composition, and for the obtained sheet-shaped test piece, the durometer hardness A is measured at 25° C. in accordance with JIS K 6253 (1997).

7. The silicone rubber-based curable composition as described in any one of 1. to 6.,

in which a tensile strength of a cured product of the silicone rubber-based curable composition, as measured under the following conditions, is equal to or more than 5.0 MPa.

(Measurement Conditions for Tensile Strength)

A dumbbell-shaped type-3 test piece is manufactured using the cured product of the silicone rubber-based curable composition, and for the obtained dumbbell-shaped type-3 test piece, the tensile strength is measured at 25° C. in accordance with JIS K 6251 (2004).

8. The silicone rubber-based curable composition as described in any one of 1. to 7.,

in which a specific surface area of the silica particles (C) as measured by a BET method is equal to or more than 200 m²/g and equal to or less than 500 m²/g.

9. The silicone rubber-based curable composition as described in any one of 1. to 8.,

in which the silicone rubber-based curable composition is used to form a molded product for a bendable member.

10. The silicone rubber-based curable composition as described in any one of 1. to 9.,

in which the silicone rubber-based curable composition is used to form a molded product for a wearable device.

11. A structure including a cured product of the silicone rubber-based curable composition as described in any one of 1. to 10.

### EXAMPLES

Hereinafter, the present invention will be described in detail with reference to Examples, but the present invention is not limited to the description of these Examples.

Raw material components used in Examples and Comparative Examples shown in Table 1 are shown below.

(Vinyl Group-Containing Organopolysiloxane (A))
Vinyl group-containing linear organopolysiloxane (A1-1a): A vinyl group-containing dimethylpolysiloxane synthesized by a synthesis scheme 1 (a structure represented by Formula (1-1), in which only R¹ (terminal) is a vinyl group)
Vinyl group-containing linear organopolysiloxane (A1-1b): A vinyl group-containing dimethylpolysiloxane synthesized by a synthesis scheme 2 (a structure represented by Formula (1-1), in which only R¹ (terminal) is a vinyl group)
Vinyl group-containing linear organopolysiloxane (A1-2a): A vinyl group-containing dimethylpolysiloxane synthesized by a synthesis scheme 3 (a structure represented by Formula (1-1), in which R¹ (terminal) and R² (in a chain) are vinyl groups)
Vinyl group-containing linear organopolysiloxane (A1-2b): A vinyl group-containing dimethylpolysiloxane synthesized by a synthesis scheme 4 (a structure represented by Formula (1-1), in which R¹ (terminal) and R² (in a chain) are vinyl groups)

(Organohydrogenpolysiloxane (B))

Manufactured by Momentive Inc.: “TC-25D”

(Silica Particles (C))
Silica particles (C-1): Silica fine particles (particle size 7 nm, specific surface area 300 m²/g), manufactured by Nippon Aerosil Co., Ltd., “AEROSIL 300”
Silica particles (C-2): Silica fine particles (particle size 16 nm, specific surface area 110 m²/g), manufactured by Nippon Aerosil Co., Ltd., “AEROSIL R^{972”}

(Silane Coupling Agent (D))
Silane coupling agent (D-1): Hexamethyldisilazane (HMDZ), manufactured by Gelest, Inc., “HEXAMETHYLDISILAZANE (SIH 6110.1)”
Silane coupling agent (D-2): Divinyltetramethyldisilazane, manufactured by Gelest, Inc., “1,3-DIVINYLTETRAMETHYLDISILAZANE (SID4612.0)”

(Platinum or Platinum Compound (E))

Manufactured by Momentive Inc.: “TC-25A”

(Synthesis of Vinyl Group-Containing Organopolysiloxane (A))

[Synthesis Scheme 1: Synthesis of Vinyl Group-Containing Linear Organopolysiloxane (A1-1a)]

A low-content vinyl group-containing linear organopolysiloxane (A1-1a) was synthesized according to Formula (5).

That is, 74.7 g (252 mmol) of octamethylcyclotetrasiloxane and 0.1 g of potassium siliconate were put into a 300 mL separable flask having a cooling pipe and a stirring blade, of which the inside had been replaced by Ar gas, and the mixture was warmed and stirred at 120° C. for 30 minutes. Further, at this time, it could be confirmed that the viscosity increased.

Thereafter, the mixture was warmed to 155° C. and continued to be stirred for 3 hours. Further, after 3 hours, 0.1 g (0.6 mmol) of 1,3-divinyltetramethyldisiloxane was added thereto, followed by further stirring at 155° C. for 4 hours.

In addition, after 4 hours, the mixture was diluted with 250 mL of toluene and then washed with water three times. The organic layer after washing was purified by reprecipitation by washing with 1.5 L of methanol several times, and the oligomer and the polymer were separated. The obtained polymer was dried at 60° C. overnight under reduced pressure to synthesize a low-content vinyl group-containing linear organopolysiloxane (A1-1a) (Mn=2.2×10⁵, Mw=4.8×10⁵). In addition, the content of vinyl groups calculated by H-NMR spectrum measurement was 0.039% by mole.

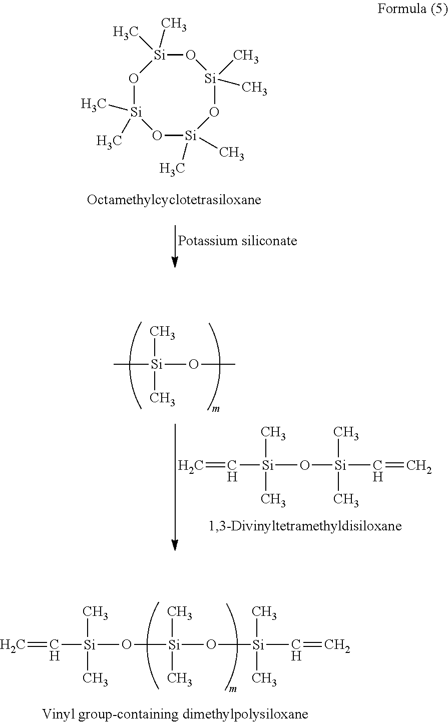

[Synthesis Scheme 2: Synthesis of Vinyl Group-Containing Linear Organopolysiloxane (A1-1b)]

A low-content vinyl group-containing linear organopolysiloxane (A1-1b) was synthesized (Mn=2.7×10⁵, Mw=5.2×10⁵) in the same manner as in the synthesis step for (A1-1a), except that the reaction time after raising the temperature to 155° C. was changed to 3.5 hours in the synthesis step for (A1-1a). In addition, the content of vinyl groups calculated by H-NMR spectrum measurement was 0.031% by mole.

[Synthesis Scheme 3: Synthesis of Vinyl Group-Containing Linear Organopolysiloxane (A1-2a)]

A vinyl group-containing linear organopolysiloxane (A1-2a) was synthesized (Mn=2.5×10⁵, Mw=5.0×10⁵) as shown in Formula (6) in the same manner as in the synthesis step for (A1-1a), except that 0.12 g (0.35 mmol) of 2,4,6,8-tetramethyl 2,4,6,8-tetravinylcyclotetrasiloxane was used in addition to 75.3 g (254 mmol) of octamethylcyclotetrasiloxane in the synthesis step for (A1-1a). In addition, the content of vinyl groups calculated by H-NMR spectrum measurement was 0.130% by mole.

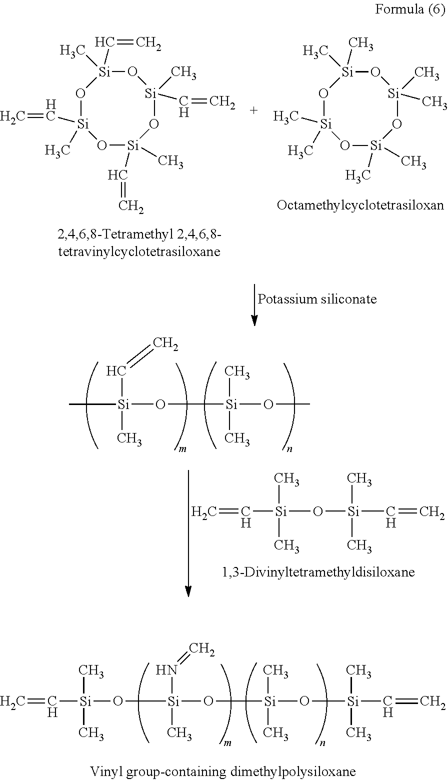

[Synthesis Scheme 4: Synthesis of Vinyl Group-Containing Linear Organopolysiloxane (A1-2b)]

A high-content vinyl group-containing linear organopolysiloxane (A1-2b) was synthesized (Mn=2.5×10⁵, Mw=5.4×10⁵) in the same manner as in the synthesis step for (A1-2a), except that the amount of octamethylcyclotetrasiloxane to be added was changed to 73.2 g (247 mmol) and the amount of 2,4,6,8-tetramethyl 2,4,6,8-tetravinylcyclotetrasiloxane to be added was changed to 2.61 g (7.6 mmol) in the synthesis step for (A1-2a). In addition, the content of vinyl groups calculated by H-NMR spectrum measurement was 2.826% by mole.

<Preparation of Silicone Rubber-Based Curable Composition>

### Test Examples 1 to 5

A mixture of the vinyl group-containing organopolysiloxane (A), the silane coupling agent (D), and water (F) was kneaded in advance at a ratio shown in Table 1 below, silica particles (C) were then added thereto, and the mixture was further kneaded to obtain a kneaded product (silicone rubber compound).

Here, the kneading after the addition of the silica particles (C) was carried out by conducting a first step of kneading the mixture for 1 hour under the condition of 60° C. to 90° C. in a nitrogen atmosphere for a coupling reaction and a second step of kneading the mixture for 2 hours under the condition of 160° C. to 180° C. in an atmosphere with reduced pressure in order to remove by-products (ammonia), followed by cooling and kneading for 20 minutes.

Subsequently, the organohydrogenpolysiloxane (B) (TC-25D) and the platinum or platinum compound (E) (TC-25A) at a ratio shown in Table 1 below were added to 100 parts by weight of the obtained kneaded product (silicone rubber compound), and the mixture was kneaded with a roll to obtain a silicone rubber-based curable composition.

TABLE 1

| | | | | | Test | Test | Test | Test | Test |
|---|---|---|---|---|---|---|---|---|---|
| | | | | Unit | Example 1 | Example 2 | Example 3 | Example 4 | Example 5 |
| Silicone | Silicone | Vinyl | A1-2a | Parts by weight | 0 | 0 | 0 | 100 | 100 |
| rubber-based | rubber | group-containing | A1-1a | | 100 | 100 | 0 | 0 | 0 |
| curable | compound | organopolysiloxane | A1-1b | | 0 | 0 | 90 | 0 | 0 |
| composition | (kneaded | (A) | A1-2b | | 0 | 0 | 10 | 0 | 0 |
| | product) | Silica particles (C) | C-1 | | 25 | 50 | 50 | 0 | 0 |
| | | | C-2 | | 0 | 0 | 0 | 20 | 35 |
| | | Silane coupling | D-1 | | 10 | 9.5 | 9.5 | 0 | 0 |
| | | agent (D) | D-2 | | 0.5 | 1.0 | 1.0 | 0 | 0 |
| | | Water (F) | | | 5.25 | 5.25 | 5.25 | 0 | 0 |
| | Additive | Crosslinking agent | Organohydrogen- | Parts by weight | 1.25 | 1.5 | 4.5 | 1.51 | 3.02 |
| | | | polysiloxane | with respect to | | | | | |
| | | | (B) | 100 parts by | | | | | |
| | | Catalytic | Platinum or | weight of | 0.5 | 0.5 | 0.5 | 0.5 | 0.5 |
| | | | platinum | kneaded product | | | | | |
| | | | compound (E) | | | | | | |

<De Mattia-Type Bending Resistance Test>

The obtained silicone rubber-based curable composition was subjected to a De Mattia-type bending resistance test measured by the following procedure, and the cut lengths in a test piece with the numbers of times of bending of 10,000, 30,000, and 50,000 were measured. The evaluation results are shown in Table 2.

(Creation of Test Piece)

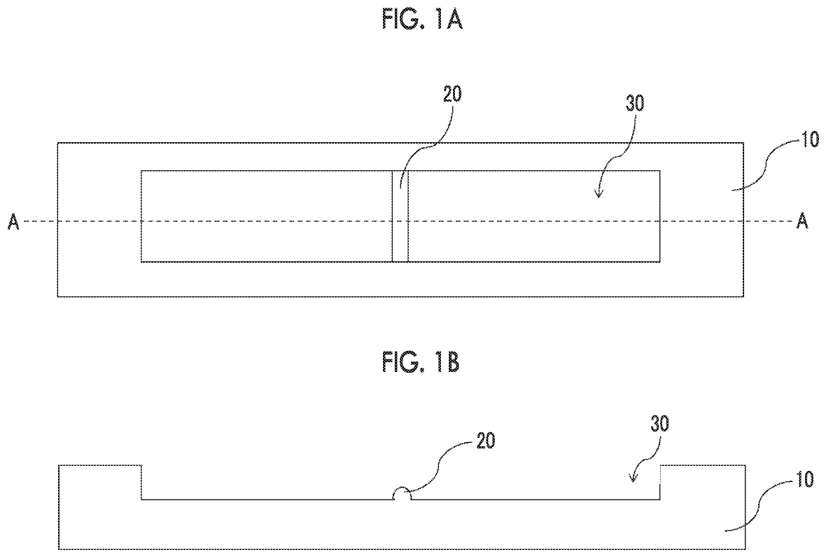

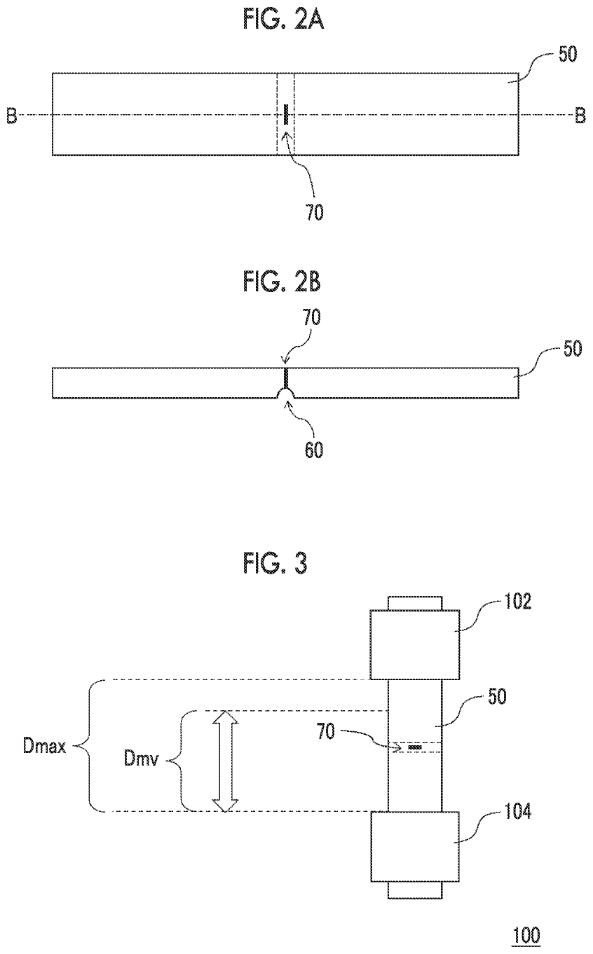

According to JIS K 6260, the obtained silicone rubber-based curable composition was put into a molding space 30 of a mold 10 shown in FIGS. 1A and 1B, pressed at 170° C. and 10 MPa for 15 minutes, and subsequently heated at 200° C. for 4 hours to manufacture a strip-shaped test piece 50 with a groove 60 (width: 25 mm, length: 150 mm, thickness: 6.3 mm). In the center of the groove 60 of the obtained test piece 50, a cut 70 having a length of 2.03 mm was made in parallel with the width direction using a blade, thereby obtaining a test piece 50 with a cut (FIGS. 2A and 2B). The cut 70 penetrated the test piece 50 in the thickness direction.

FIG. 1A shows a top view of the mold 10, and FIG. 1B shows a sectional side view of the mold 10 as fragmentarily viewed in the direction of an arrow A-A. The mold 10 is provided with a curved convex portion 20 on a bottom surface of the molding space 30.

In addition, FIG. 2A shows a top view of the test piece 50 with the groove 60 in which the cut 70 is formed, and FIG. 2B shows a sectional side view of the test piece 50 as fragmentarily viewed in the direction of an arrow B-B.

(Procedure)

As shown in FIG. 3, the test piece 50 obtained in (Creation of Test Piece) above was held between a fixed gripper 102 and a movable gripper 104 of a tester 100 (De Mattia bending-cracking tester).

Specifically, the test piece 50 was attached to the grippers so that a distance between the two grippers was maximized and the center of the groove 60 of the test piece 50 was located in the center between the grippers. At this time, the test piece 50 was held flat so as not to impart extra distortion.

Subsequently, the movable gripper 104 was reciprocated in the vertical direction with reference to the fixed gripper 102, based on the following test conditions. The movable gripper 104 approached the fixed gripper 102 (the test piece 50 was bent) from a maximum distance to a reciprocating distance, then the movable gripper 104 was separated up to the maximum distance (the test piece 50 was flat), which was defined as one reciprocation (one cycle), and the number of cycles (times) was defined as the number of times of bending.

The lengths (mm) of the cut 70 in the test piece 50 with the numbers of times of bending of 10,000, 30,000, and 50,000 were measured using a digital caliper (manufactured by Mitutoyo Corporation).

Furthermore, the length of the cut 70 was taken as an average value of the three measured values measured by performing the De Mattia-type bending resistance test three times. The results are shown in Table 2.

A ratio of change in the cut length was calculated based on an expression: L₅/L₀.

L₀ was an initial cut length before the De Mattia-type bending resistance test, and L₁, L₃, and L₅ were each an average length of cuts with the numbers of times of bending of 10,000, 30,000, and 50,000 after the De Mattia-type bending resistance test, respectively.

(Test Conditions)
Test standard: In accordance with JIS K 6260 (2017)
Tester: De Mattia bending-cracking tester with a low-temperature tank (manufactured by Yasuda Seiki Seisakusho Ltd.)
Test temperature: 23±2° C.
Maximum distance between grippers: 75 mm (Dₘₐₓ in FIG. 3)
Reciprocating distance: 57 mm (Dₘᵥ in FIG. 3)
Condition adjustment: Before the start of the first test, the mixture was left to stand at 23° C. for 10 minutes. Before the start of the second and third tests, the mixture was left to stand in the same environment for 5 minutes.
Test speed: 300±10 times/minute
Number of tests: n=3

In <De Mattia-Type Bending Resistance Test> above, a case where the test piece broke with the numbers of times of bending of 10,000, 30,000, and 50,000 was set to 25.0 mm.

TABLE 2

| | | | | | | Comparative | Comparative |
|---|---|---|---|---|---|---|---|
| | | Unit | Example 1 | Example 2 | Example 3 | Example 1 | Example 2 |
| Silicone rubber-based curable | | | Test Example 1 | Test Example 2 | Test Example 3 | Test Example 4 | Test Example 5 |
| composition | | | | | | | |
| Cut | 10,000 times (L1) | mm | 3.8 | 5.7 | 9.2 | 21.7 | 25.0 |
| length | 30,000 times (L3) | mm | 5.4 | 8.7 | 9.7 | 24.0 | 25.0 |
| | 50,000 times (L5) | mm | 6.3 | 10.4 | 11.0 | 24.1 | 25.0 |
| | L1/L0 | | 1.9 | 2.8 | 4.5 | 10.7 | 12.3 |
| | Ratio of change (L5/L0) | | 3.1 | 5.1 | 5.4 | 11.9 | 12.3 |

| | | | | | | |
|---|---|---|---|---|---|---|
| Type A durometer hardness | | 22.7 | 40.8 | 62.4 | 21.5 | 50.4 |
| Tear strength | N/mm | 37.7 | 51.7 | 52.4 | 18.8 | 7.6 |
| Tensile strength | MPa | 14.3 | 8.3 | 10.7 | 5.0 | 8.5 |
| Elongation at break | % | 1442 | 912 | 783 | 494 | 292 |
| Durability against repeated bending | | A | A | A | B | B |
| deformation | | | | | | |

Based on the results of the obtained cut lengths, Test Examples 1, 2, and 3 were designated as Examples 1, 2, and 3, respectively, and Test Examples 4 and 5 were designated as Comparative Examples 1 and 2, respectively.

The obtained silicone rubber-based curable compositions of Examples and Comparative Examples were evaluated based on the following evaluation items.

<Manufacture of Silicone Rubber>

The obtained silicone rubber-based curable composition was pressed at 170° C. and 10 MPa for 15 minutes to perform a primary curing while forming a sheet having a thickness of 1 mm. Subsequently, the composition was heated at 200° C. for 4 hours to perform a secondary curing.

Thus, a sheet-shaped silicone rubber (a cured product of the silicone rubber-based curable composition) was obtained.

Using two samples, a hardness was measured at n=5 in each sample, and an average value of a total of ten measurements was taken as the measured value. A tensile stress and an elongation at break were measured with three samples, and an average value from the three measurements was taken as the measured value. A tear strength was measured with five samples, and an average value of the five measurements was taken as the measured value.

Each of the average values is shown in Table 2.

(Hardness)

Six sheets of the obtained sheet-shaped silicone rubber having a thickness of 1 mm were laminated to prepare a test piece having a thickness of 6 mm. A type A durometer hardness of the obtained test piece was measured at 25° C. in accordance with JIS K 6253 (1997).

(Tear Strength)

A crescent-shaped test piece was manufactured in accordance with JIS K 6252 (2001) using the obtained sheet-shaped silicone rubber having a thickness of 1 mm, and a tear strength of the obtained crescent-shaped test piece was measured at 25° C. The unit is N/mm.

(Tensile Strength)

A dumbbell-shaped type-3 test piece was manufactured in accordance with JIS K 6251 (2004) using the obtained sheet-shaped silicone rubber having a thickness of 1 mm, and a tensile strength of the obtained dumbbell-shaped type-3 test piece was measured at 25° C. The unit is MPa.

(Elongation at Break)

A dumbbell-shaped type-3 test piece was manufactured in accordance with JIS K 6251 (2004) using the obtained sheet-shaped silicone rubber having a thickness of 1 mm, and an elongation at break of the obtained dumbbell-shaped type-3 test piece was measured at 25° C. The elongation at break was calculated by [Moving distance (mm) between chucks]÷[Initial distance (60 mm) between chucks]×100. The unit is %

(Evaluation of Durability)

A tubular member (tube) having a thickness of 1 mm×an inner diameter of 2 mm was created by using the silicone rubber-based curable composition obtained in each of Examples and each of Comparative Examples to perform a curing under the conditions of 170° C. for 5 minutes and 200° C. for 4 hours. A durability test sample in which a steel wire (manufactured by TRUSCO Nakayama Co., Ltd., steel wire, small roll type wire diameter of 1.6 mm×15 m) was inserted in the obtained tubular member was prepared, and subjected to a durability test. Specifically, a 90° bending test of the durability test sample was repeated 100 times to determine the durability. Tubular members with no abnormal appearance after the test were marked with A, and tubular members with cracks or damage after the test were marked with B.

In addition, the number of times of bending until the test piece broke was measured in the same manner as in <De Mattia-Type Bending Resistance Test> above, except that the test piece in which a cut had not been made was used. In Examples 1 to 3, no break was observed at 10,000 times or 100,000 times, and the number of times of bending up to breaking was larger in the order of Examples 3, 2, and 1.

Among these, it was found that Examples 1 and 2 were excellent in the bending-cracking resistance, as compared with Example 3.

It was found that the cured products of the silicone rubber-based curable compositions of Examples 1 to 3 were excellent in durability to repeated bending deformation, as compared with Comparative Examples 1 and 2. The molded products of such silicone rubber-based curable compositions of Examples 1 to 3 can be suitably used for a bendable member, preferably a wearable device having a wiring or wiring substrate, and more preferably a wiring substrate of a wearable device.

This application claims priority based on Japanese application Japanese Patent Application No. 2019-043023 filed on Mar. 8, 2019, the contents of all of which are hereby incorporated by reference in their entireties.

What is claim is:

1. A silicone rubber-based curable composition comprising:
a vinyl group-containing organopolysiloxane (A); and
silica particles (C),
wherein in a case where a De Mattia-type bending resistance test in accordance with JIS K 6260 is performed using a test piece formed of a cured product of the silicone rubber-based curable composition, a ratio (L₅/L₀) of change in a cut length in the test piece with the number of times of bending of 50,000 is equal to or more than 1.1 and equal to or less than 11.5, the ratio being measured on the basis of the following procedure:
(Procedure)
the silicone rubber-based curable composition is pressed at 170° C. and 10 MPa for 15 minutes, and subsequently heated at 200° C. for 4 hours to manufacture a strip-shaped test piece having a width of 25 mm, a length of 150 mm, and a thickness of 6.3 mm in accordance with JIS K 6260,
in the center of the obtained test piece, a cut having a length of 2.03 mm, penetrating the test piece, is formed in parallel to a width direction, and the initial cut length is defined as L₀,
subsequently, the test piece with the cut is attached between grippers of a tester, the De Mattia-type bending resistance test is performed based on the following test conditions, and a cut length (mm) in the test piece after a predetermined number of times of bending is measured,
an average value in a case where the De Mattia-type bending resistance test is performed three times is used as the cut length, and the average value of the cut length is defined as L₅,
the ratio of change in the cut length is calculated based on an expression: L₅/L₀;
(Test Conditions)
Test standard: In accordance with JIS K 6260
Tester: De Mattia bending-cracking tester
Test temperature: 23±2° C.
Maximum distance between grippers: 75 mm
Reciprocating distance: 57 mm
Test speed: 300±10 times/minute
Number of tests: n=3.

2. The silicone rubber-based curable composition according to claim 1,
wherein in a case where the De Mattia-type bending resistance test based on the procedure is performed and a cut length in the test piece with the number of times of bending of 10,000 is defined as L₁, L₁/L₀ satisfies a range of equal to or more than 1.0 and equal to or less than 10.0.

3. The silicone rubber-based curable composition according to claim 1,
wherein a content of the silica particles (C) is equal to or more than 10 parts by weight and equal to or less than 35 parts by weight with respect to a total of 100 parts by weight of the vinyl group-containing organopolysiloxane (A).

4. The silicone rubber-based curable composition according to claim 1,
wherein a tear strength of the silicone rubber-based curable composition, as measured under the following conditions, is equal to or more than 25 N/mm:
(Measurement Conditions for Tear Strength)
a crescent-shaped test piece is manufactured using a cured product of the silicone rubber-based curable composition, and for the obtained crescent-shaped test piece, a tear strength is measured at 25° C. in accordance with JIS K 6252 (2001).

5. The silicone rubber-based curable composition according to claim 1,
wherein an elongation at break of a cured product of the silicone rubber-based curable composition, as measured under the following conditions, is equal to or more than 500%:
(Measurement Conditions for Elongation at Break)
a dumbbell-shaped type-3 test piece is manufactured in accordance with JIS K 6251 (2004), using the cured product of the silicone rubber-based curable composition, and an elongation at break of the obtained dumbbell-shaped type-3 test piece is measured at 25° C., the elongation at break is calculated by [Moving distance (mm) between chucks]÷[Initial distance (60 mm) between chucks]×100, and the unit is %.

6. The silicone rubber-based curable composition according to claim 1,
wherein a durometer hardness A of a cured product of the silicone rubber-based curable composition, as measured under the following conditions, is equal to or more than 10 and equal to or less than 70:
(Measurement Conditions for Durometer Hardness A)
a sheet-shaped test piece is manufactured using the cured product of the silicone rubber-based curable composition, and for the obtained sheet-shaped test piece, the durometer hardness A is measured at 25° C. in accordance with JIS K 6253 (1997).

7. The silicone rubber-based curable composition according to claim 1,
wherein a tensile strength of a cured product of the silicone rubber-based curable composition, as measured under the following conditions, is equal to or more than 5.0 MPa:
(Measurement Conditions for Tensile Strength)
a dumbbell-shaped type-3 test piece is manufactured using the cured product of the silicone rubber-based curable composition, and for the obtained dumbbell-shaped type-3 test piece, the tensile strength is measured at 25° C. in accordance with JIS K 6251 (2004).

8. The silicone rubber-based curable composition according to claim 1,
wherein a specific surface area of the silica particles (C) as measured by a BET method is equal to or more than 200 m²/g and equal to or less than 500 m²/g.

9. The silicone rubber-based curable composition according to claim 1,
wherein the vinyl group-containing organopolysiloxane (A) includes a vinyl group-containing linear organopolysiloxane (A1) represented by General Formula (1-1), 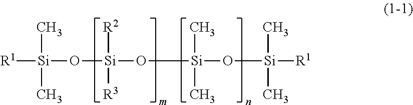
(in General Formula (1-1), R¹ is a vinyl group, R² is a methyl group or a vinyl group, m is an integer of 0 to 2,000, and n is an integer of 1,000 to 10,000).

10. The silicone rubber-based curable composition according to claim 1,
wherein the vinyl group-containing organopolysiloxane (A) includes a vinyl group-containing linear organopolysiloxane (A1) having a content of vinyl groups of equal to or less than 0.4% by mole.

11. The silicone rubber-based curable composition according to claim 1,
wherein the silicone rubber-based curable composition is used to form a part of a configuration of a wearable device.

12. The silicone rubber-based curable composition according to claim 11,
wherein the silicone rubber-based curable composition is used to form a wiring and/or a substrate in a wiring substrate of a wearable device.

13. The silicone rubber-based curable composition according to claim 11,
wherein the wearable device can be worn on a curved surface of a body or clothes.

14. A structure comprising a cured product of the silicone rubber-based curable composition according to claim 1.

15. A wearable device comprising a wiring substrate including a wiring and a substrate,
wherein a part of the wiring and/or the substrate in the wiring substrate is formed of a cured product of the silicone rubber-based curable composition according to claim 1.

16. A method for manufacturing a structure, comprising:
a step of curing the silicone rubber-based curable composition according to claim 1; and
a step of obtaining a structure including a cured product of the silicone rubber-based curable composition.

17. The method for manufacturing a structure according to claim 16,
wherein the structure is a wearable device in the step of obtaining a structure.
